(19) United States
(12) Patent Application Publication
(10) Pub. No.: US 2013/0153275 A1
(43) Pub. Date: Jun. 20, 2013

(54) PRINTED CIRCUIT BOARD AND METHOD FOR MANUFACTURING THE SAME

(71) Applicants: Jin Gul Hyun, Gyunggi-do (KR); Jin Gu Kim, Gyunggi-do (KR); Young Do Kweon, Seoul (KR); Hyung Jin Jeon, Gyunggi-do (KR)

(72) Inventors: Jin Gul Hyun, Gyunggi-do (KR); Jin Gu Kim, Gyunggi-do (KR); Young Do Kweon, Seoul (KR); Hyung Jin Jeon, Gyunggi-do (KR)

(73) Assignee: SAMSUNG ELECTRO-MECHANICS CO., LTD., Gyunggi-do (KR)

(21) Appl. No.: 13/425,665

(22) Filed: Mar. 21, 2012

(30) Foreign Application Priority Data
Dec. 19, 2011 (KR) 1020110137179

(51) Int. Cl. H05K 1/00; H05K 3/28; H05K 3/10

(52) U.S. Cl. 174/258; 174/250; 29/848

(57) ABSTRACT

Disclosed herein are a printed circuit board and a method for manufacturing the same. According to a preferred embodiment of the present invention, the printed circuit board includes: a base substrate; circuit patterns formed in a circuit region on the base substrate; dummy patterns formed in a dummy region on the base substrate; and an insulating layer formed above the circuit patterns and the dummy patterns by a slit die coating method.

### CROSS REFERENCE TO RELATED APPLICATION

This application claims the benefit of Korean Patent Application No. 10-2011-0137179, filed on Dec. 19, 2011, entitled “Printed Circuit Board and Method of Manufacturing a Printed Circuit Board,” which is hereby incorporated by reference in its entirety into this application.

### BACKGROUND OF THE INVENTION

1. Technical Field

The present invention relates to a printed circuit board and a method for manufacturing the same.

2. Description of the Related Art

A printed circuit board (PCB) serves to electrically connect mounted parts with one another through wiring patterns formed on insulating members, such as a phenol resin insulating plate, an epoxy resin insulating plate, or the like, and mechanically fix parts while supplying power, or the like. An example of the printed circuit board may include a one-side PCB in which wirings are formed on only one surface of an insulating substrate, and a double-side PCB in which wirings are formed on both sides, and a multi layered board (MLB) on which wires are formed in multiple layers. Here, at the time of forming the printed circuit board, it is important to ensure planarization of an insulating layer so as to form the reliable wiring patterns. In order to uniformly distribute the insulating layer, a spin on glass method has been used. However, even though the insulating layer is formed by the spin on glass method, it is difficult to ensure the planarization of the insulating layer by a step between the wiring patterns and a space in which the wiring patterns are not formed.

Further, in order to ensure the planarization of the insulating layer, a method for forming dummy patterns in an empty space in which the wiring patterns are not formed has been used (Korean Patent No. 10-0290477). However, the method for forming dummy patterns has also a limitation in ensuring the planarization of the insulating layer.

### SUMMARY OF THE INVENTION

The present invention has been made in an effort to provide a printed circuit board having a planarized insulating layer and a method for manufacturing the same.

According to a preferred embodiment of the present invention, there is provided a printed circuit board, including: a base substrate; circuit patterns formed in a circuit region on the base substrate; dummy patterns formed in a dummy region on the base substrate; and an insulating layer formed above the circuit patterns and the dummy patterns by a slit die coating method.

A distance between the circuit pattern and the dummy pattern may be changed according to a thickness of the circuit pattern or the dummy pattern.

The distance between the circuit pattern and the dummy pattern may be changed according to a maximum thickness of the insulating layer formed above the circuit pattern or the dummy pattern.

A distance between the circuit pattern and the dummy pattern may be

$$D \leq \frac{T 2}{T 1} \times \frac{100}{1.2} .$$

(where D represents the distance between the circuit pattern and the dummy pattern, T1 represents the thickness of the circuit pattern, and T2 represents the maximum thickness of the insulating layer formed above the circuit pattern or the dummy pattern).

A difference between the maximum thickness and the minimum thickness of the insulating layer may be 10% or less of the maximum thickness of the insulating layer formed above the circuit pattern or the dummy pattern.

A difference between the maximum thickness and a minimum thickness of the insulating layer may be 3 μm or less.

The maximum thickness of the insulating layer may be 100 μm.

According to another preferred embodiment of the present invention, there is provided a method for manufacturing a printed circuit board, including: preparing a base substrate; forming circuit patterns and dummy patterns on the base substrate; and forming an insulating layer above the circuit patterns and the dummy patterns on the base substrate by a slit die coating method.

At the forming of the circuit patterns and the dummy patterns, a distance between the circuit pattern and the dummy pattern may be changed according to a thickness of the circuit pattern or the dummy pattern.

At the forming of the circuit patterns and the dummy patterns, the distance between the circuit pattern and the dummy pattern may be changed according to a maximum thickness of the insulating layer formed above the circuit pattern or the dummy pattern.

At the forming of the circuit patterns and the dummy patterns, a distance between the circuit pattern and the dummy pattern may be

$$D \leq \frac{T 2}{T 1} \times \frac{100}{1.2} .$$

(where D represents the distance between the circuit pattern and the dummy pattern, T1 represents the thickness between the circuit patterns or the dummy pattern, and T2 represents the maximum thickness of the insulating layer formed above the circuit pattern or the dummy pattern).

At the forming of the insulating layer, a difference between the maximum thickness and the minimum thickness of the insulating layer may be 10% or less of the maximum thickness of the insulating layer formed above the circuit pattern or the dummy pattern.

At the forming of the insulating layer, a difference between the maximum thickness and a minimum thickness of the insulating layer may be 3 μm or less.

At the preparing of the base substrate, the base substrate may be an organic substrate or an organic composite substrate.

The maximum thickness of the insulating layer may be 100 μm.

### BRIEF DESCRIPTION OF THE DRAWINGS

FIG. 1 is an exemplified diagram showing a printed circuit board according to a preferred embodiment of the present invention;

FIGS. 2 and 3 are diagrams sequentially showing a process of a method for manufacturing a printed circuit board according to a preferred embodiment of the present invention;

FIG. 4 is an exemplified diagram showing a printed circuit board according to a technology of forming an insulating layer of the prior art;

FIG. 5 is an exemplified diagram showing a printed circuit board according to another technology of forming an insulating layer of the prior art;

FIG. 6 is an exemplified diagram showing a printed circuit board according to the preferred embodiment of the present invention;

FIG. 7 is an exemplified diagram showing a printed circuit board according to the preferred embodiment of the present invention;

FIG. 8 is an exemplified diagram showing a printed circuit board according to another preferred embodiment of the present invention;

FIG. 9 is an exemplified diagram showing a distance between circuit patterns and dummy patterns of the printed circuit board according to the preferred embodiment of the present invention; and

FIG. 10 is an exemplified diagram showing flatness of an insulating layer of the printed circuit board according to the preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, a printed circuit board and a method for manufacturing the same according to preferred embodiments of the present invention will be described in detail with reference to the accompanying drawings.

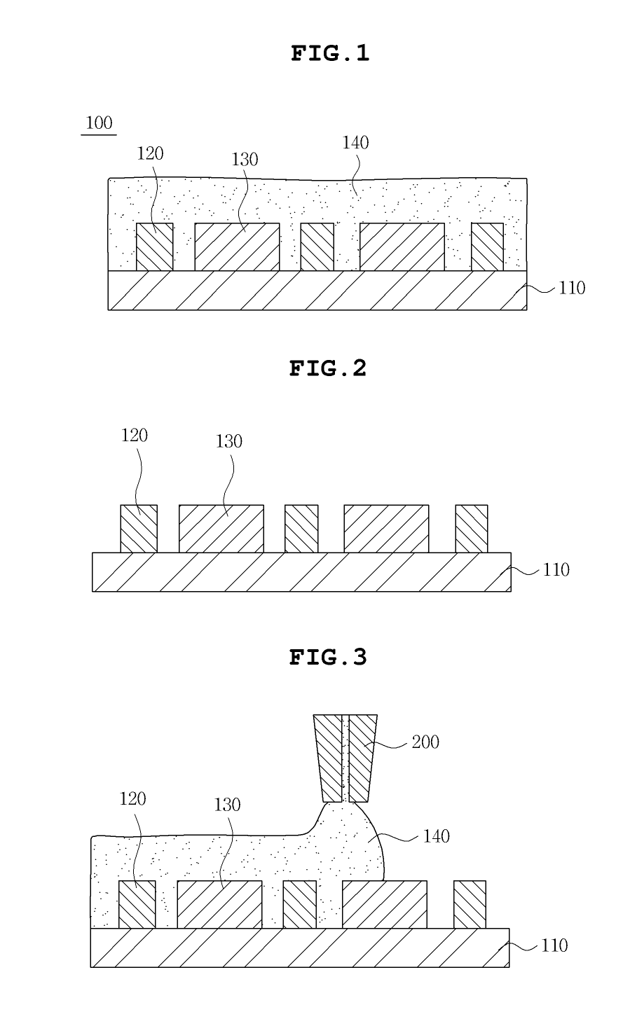

FIG. 1 is an exemplified diagram showing a printed circuit board according to the preferred embodiment of the present invention. Referring to FIG. 1, a printed circuit board 100 may include a base substrate 110, circuit patterns 120, dummy patterns 130, and an insulating layer 140.

The printed circuit board 100 may be used for mounting parts and wirings of electronic devices. The printed circuit board 100 may be a one-sided printed circuit board (PCB) forming circuit layers including the circuit patterns 120 on one surface of a base substrate 110 or a double-sided PCB having the circuit layers formed on both surfaces thereof. Alternatively, the printed circuit board 100 may be a multi layered board (MLB) on which circuit layers are formed in multiple layers.

The base substrate 110 may be made of a hard material capable of supporting a build up printed circuit board. For example, the base substrate 110 may be an organic substrate or an organic composite substrate. In addition, although not shown on the base substrate 110, a through via may be formed. When the circuit layers are formed on both surfaces of the printed circuit board 100, the through via may be foinied to provide electrical signal connection between the circuit layers formed on both surfaces thereof.

The circuit pattern 120 is a conductive line formed on the base substrate 110 that transfers electrical signals according to a design pattern. That is, the circuit patterns 120 may be formed in a circuit region on the base substrate 110. The circuit pattern 120 may be made of conductive metals such as gold, silver, copper, nickel, or the like.

The dummy pattern 130 is a metal pattern formed in a dummy region on the base substrate 110. In the preferred embodiment of the present invention, the dummy region is named as a region in which the circuit patterns 120 are not formed, in the printed circuit board 100. That is, the dummy region may be a region between the circuit patterns 120.

When the insulating layer 140 is formed above the circuit pattern 120, the dummy pattern 130 may be a complementary member so as to prevent a step of the insulating layer 140 from being formed in a space between the circuit patterns 120. The dummy pattern 130 may be made of metals such as gold, silver, copper, nickel, or the like. In the preferred embodiment of the present invention, the dummy pattern 130 may be made of the same metals as the circuit pattern 120. In addition, when the circuit pattern 120 is formed, the dummy patterns 130 may be simultaneously formed. The uniform insulating layer 140 may be formed above the circuit pattern 120 by the dummy pattern 130 formed as described above.

The insulating layer 140 may be formed above the circuit pattern 120 and the dummy pattern 130. That is, the insulating layer 140 may be framed above the base substrate 110 while impregnating the circuit pattern 120 and the dummy pattern 130. The insulating layer 140 may be made of ajinomoto build up film (ABF), prepreg, epoxy resin, modified epoxy resin, bisphenol A resin, epoxy-novolac resin, and aramid reinforced, glass fiber reinforced, or paper reinforced epoxy resin. Here, the insulating layer 140 may be formed by a slit die coating method. The slit die coating method is a method for forming an insulating layer by applying an insulating material to an upper of the base substrate 110 so that the circuit pattern 120 and the dummy pattern 130 are impregnated by using a slit die device. Here, the slit die device is a device used to form a coating layer by discharging and applying a predetermined amount of coating liquid to the substrate. The uniform insulating layer may be formed by forming the insulating layer by the slit die coating. In addition, it is possible to prevent voids from occurring when the insulating layer is formed between the circuit pattern 120 and the dummy pattern 130 by the slit die coating. According to the preferred embodiment of the present invention, a maximum thickness of the insulating layer 140 may be 100 μm. This is a maximum thickness of the insulating layer that can be formed by the slit die coating method using the slit die device.

Meanwhile, the preferred embodiment of the present invention describes that the circuit pattern 120, the dummy pattern 130, and the insulating layer 140 are formed on only one surface of the base substrate 110, but is only an example. Therefore, the circuit pattern 120, the dummy pattern 130, and the insulating layer 140 can be formed on both surfaces of the base substrate 110.

FIGS. 2 and 3 are flow charts showing a method for manufacturing a printed circuit board according to a preferred embodiment of the present invention.

Referring to FIG. 2, the circuit pattern 120 and the dummy pattern 130 may first be formed on the upper of the base substrate 110.

The base substrate 110 may be made of a hard material capable of supporting a build up printed circuit board. For example, the base substrate 110 may be an organic substrate or an organic composite substrate.

In addition, although not shown on the base substrate 110, a through via may be formed. When the circuit layers are formed on both surfaces of the printed circuit board 100, the through via may be formed to provide electrical signal connection between the circuit layers formed on both surfaces thereof.

The circuit pattern 120 and the dummy pattern 130 may be simultaneously formed. The circuit pattern 120 is a conductive line formed on the base substrate 110 that transfers electrical signals according to a design pattern. The circuit pattern 120 may be made of conductive metals such as gold, silver, copper, nickel, or the like. The dummy pattern 130 may be formed between the empty space between the circuit patterns 120. In the preferred embodiment of the present invention, the dummy pattern 130 is formed in an empty space between the circuit patterns 120 but a position at which the dummy pattern 130 is formed is not limited thereto. That is, the dummy pattern 130 may be formed at any place in which any component including the circuit pattern 120 is not formed.

The circuit pattern 120 may be formed by a known method and the dummy pattern 130 may be formed simultaneously with forming the circuit pattern 120. For example, a plating resist patterned for forming the circuit pattern 120 and the dummy pattern may be formed on the upper of the base substrate 110. Thereafter, the plating is performed with the conductive metals by using the electroplating method and the circuit pattern 120 and the dummy pattern 130 may be simultaneously formed on the upper of the base substrate 110 by removing the plating resist.

Referring to FIG. 3, the insulating layer 140 may be formed above the circuit pattern 120 and the dummy pattern 130.

The insulating layer 140 may be formed on the upper of the base substrate 110 having the circuit pattern 120 and the dummy pattern 130 formed thereon by the slit die coating method. That is, the insulating material may be applied above the circuit pattern 120 and the dummy pattern 130 by the slit die device 200. The insulating layer 140 may be formed by discharging a predetermined amount of insulating material onto the circuit pattern 120 and the dummy pattern 130 while the slit die device 200 moves a period in which the insulating layer 140 is formed in a predetermined direction at a predetermined speed.

In this case, an example of the insulating material may include ajinomoto build up film (ABF), prepreg, epoxy resin, modified epoxy resin, bisphenol A resin, epoxy-novolac resin, and aramid reinforced, glass fiber reinforced, or paper reinforced epoxy resin. In addition, the insulating material may be discharged in a liquid state from the slit die device 200.

At the time of forming the insulating layer 140 by the above-mentioned slit die device 200, the insulating material may be applied to the narrow empty space between the patterns such as the circuit pattern 120 and the dummy pattern 130 as the insulating material in the liquid state is discharged from the slit die device 200. Therefore, at the time of forming the insulating layer 140 by the slit die method, it is possible to prevent the voids from being formed in the narrow empty space between the patterns. According to the preferred embodiment of the present invention, a maximum thickness of the insulating layer 140 may be 100 μm. This is the maximum thickness of the insulating layer 140 that can be formed by the slit die coating method using the slit die device.

Further, it is possible to prevent the step between the insulating layer 140 formed above the circuit pattern 120 and the insulating layer 140 formed in the empty space from occurring by formng the dummy pattern 130 in a wide empty space between the circuit patterns 120.

Meanwhile, the preferred embodiment of the present invention describes that the circuit pattern 120, the dummy pattern 130, and the insulating layer 140 are formed on only one surface of the base substrate 110, but is only an example. Therefore, the circuit pattern 120, the dummy pattern 130, and the insulating layer 140 can be formed on both surfaces of the base substrate 110.

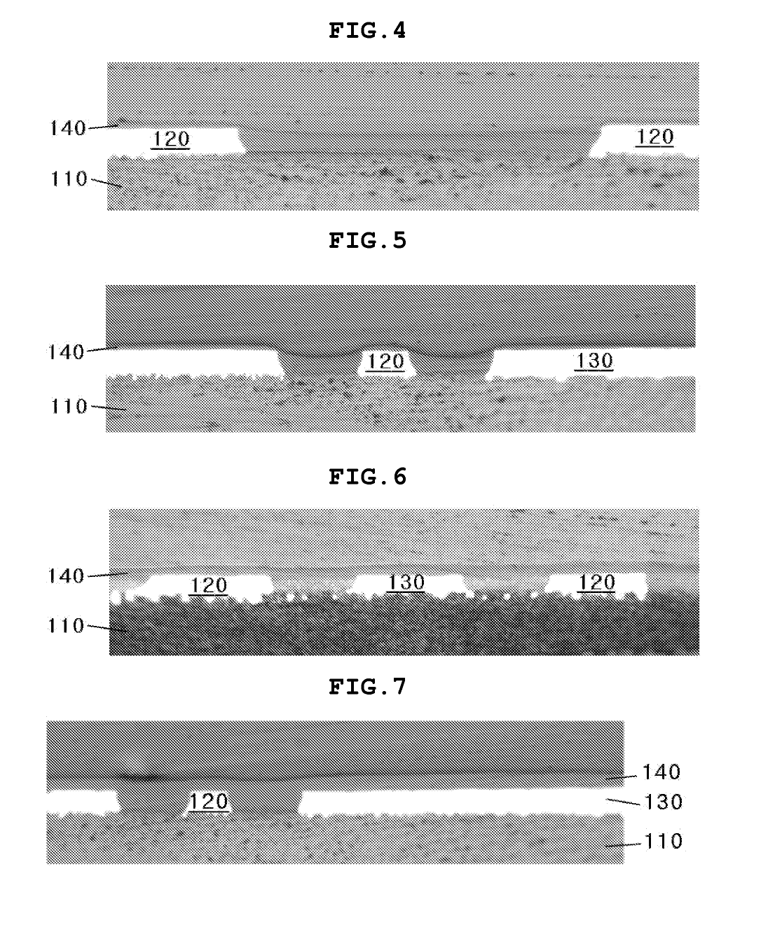

FIG. 4 is an exemplified diagram showing a printed circuit board according to a technology of forming an insulating layer of the prior art.

Referring to FIG. 4, in the printed circuit board of the prior art, the insulating layer 140 is formed above the circuit pattern 120 foamed on the upper of the base substrate 110. In this case, the insulating layer 140 may be formed by the spin on glass method. The spin on glass method is one of the methods used to ensure the planarization of the insulating layer 140. As described above, it can be confirmed from FIG. 4 that the insulting layer 140 formed above the circuit pattern 120 by the spin on glass method has a large step between the maximum thickness and the minimum thickness.

FIG. 5 is an exemplified diagram showing a printed circuit board according to another technology of forming an insulating layer of the prior art.

Referring to FIG. 5, in the printed circuit board of the related art, the dummy patterns 130 are formed in the dummy region on the base substrate 110 on which the circuit patterns 120 are formed. In addition, the insulating layer 140 is formed above the circuit pattern 120 and the dummy pattern 130 by the spin on glass method. As described above, it can be confirmed from FIG. 5 that the dummy pattern 130 and the insulting layer 140 formed above the circuit pattern by the spin on glass method has a large step between the maximum thickness and the minimum thickness even though the dummy pattern 130 is formed.

FIG. 6 is an exemplified diagram showing a printed circuit board according to the preferred embodiment of the present invention.

Referring to FIG. 6, in the printed circuit board according to the preferred embodiment of the present invention, the dummy patterns 130 are formed in the dummy region on the base substrate 110 on which the circuit patterns 120 are formed. In addition, the insulating layer 140 is formed above the circuit pattern 120 and the dummy pattern 130 by the slit die coating method. As described above, after the dummy pattern 130 is formed in the dummy region according to the preferred embodiment of the present invention, it can be confirmed from FIG. 6 that the insulating layer 140 formed above the circuit pattern 120 and the dummy pattern 130 by the slit die coating method hardly have a step between the maximum thickness and the minimum thickness.

That is, as a result of comparing FIGS. 4 and 5 according to the prior art with FIG. 6 according to the preferred embodiment of the present invention, it can be confirmed that the method according to the preferred embodiment of the present invention can form more planarized insulating layer 140 than the method according to the prior art.

FIG. 7 is an exemplified diagram showing a printed circuit board according to the preferred embodiment of the present invention.

FIG. 7 shows the printed circuit board formed according to the method of FIGS. 2 and 3 according to the preferred embodiment of the present invention.

The base substrate 110, the circuit patterns 120, the dummy patterns 130, and the insulating layer 140 can be confirmed from FIG. 7.

Here, the circuit pattern formed on the upper of the base substrate 110 may be formed at a thickness of 8 μm. In addition, the dummy pattern 130 formed on the upper of the base substrate 110 may be formed at a thickness of 8 μm. In addition, the insulating layer 140 may be formed above the circuit pattern 120 and the dummy pattern 130 formed on the base substrate 110 by the slit die coating method. In this case, the insulating layer 140 may be formed at a thickness of 6 μm from above the circuit pattern 130 and the dummy pattern 130.

In the printed circuit board 100 formed as described above, it can be confirmed that the voids are not formed in the region between the circuit pattern 120 and the dummy pattern 130 when applying the insulating layer 140. In addition, it can be confirmed that a difference between the maximum thickness and the minimum thickness of the applied insulating layer 140 is 3 μm or less.

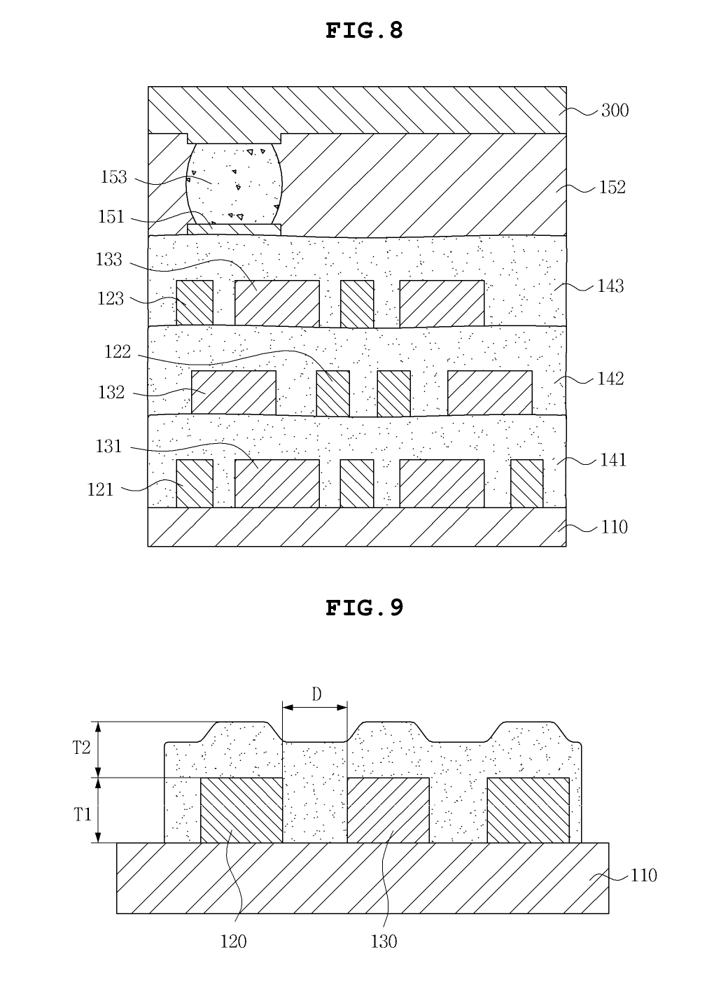

FIG. 8 is an exemplified diagram showing a printed circuit board according to another preferred embodiment of the present invention.

Referring to FIG. 8, the printed circuit board 100 is a printed circuit board in which a multi layered circuit layer is built up. The printed circuit board 100 may include the base substrate 110, a build up layer 160, a bump 153, and a solder resist 152.

The base substrate 110 may be made of a hard material capable of supporting the build up circuit layer. For example, the base substrate 100 may be a metal plate or an insulating member. Here, the metal plate may be a copper clad and the insulating member may be made of a composite polymer resin. Alternatively, the base substrate 110 adopts the ajinomoto build up film (ABF) to easily implement fine circuits or adopts the prepreg to thinly manufacture the printed circuit board. However, the base substrate is not limited thereto, but may be made of a hard insulating material including epoxy resin or modified epoxy resin, bisphenol A resin, epoxy-novolac resin, aramid reinforced, glass fiber reinforced, or paper reinforced epoxy resin.

In addition, although not shown on the base substrate 110, a through via may be formed. When the circuit layers are formed on both surfaces of the printed circuit board 100, the through via may be formed to provide electrical signal connection between the circuit layers formed on both surfaces thereof.

The build up layer 160 may be formed on the upper of the base substrate 110. According to the preferred embodiment of the present invention, the build up layer 160 may be formed in a structure in which the plurality of circuit patterns 120, the plurality of dummy patterns 130, and the plurality of insulating layers 140 are stacked. Here, the circuit pattern 120 is a conductive line formed on the base substrate 110 that transfers electrical signals according to a design pattern. The circuit pattern 120 may be made of conductive metals such as gold, silver, copper, nickel, or the like. In addition, the dummy pattern 130, which is formed in a region in which the circuit patterns are not formed, may be referred to as a complementary member so as to uniformly apply the insulating layer 140 formed above the circuit pattern 120. The dummy pattern 130 as described above may be made of metals such as gold, silver, copper, nickel, or the like. In the preferred embodiment of the present invention, the circuit pattern 120 and the dummy pattern 130 are simultaneously formed and may be made of the same materials. In addition, the insulating layer 140 may be made of ajinomoto build up film (ABF), prepreg, epoxy resin, modified epoxy resin, bisphenol A resin, epoxy-novolac resin, and aramid reinforced, glass fiber reinforced, or paper reinforced epoxy resin. According to the preferred embodiment of the present invention, the insulating layer 140 may be formed by the slit die coating method using the slit die device.

The build up layer 160 may include a first circuit pattern 121 and a first dummy pattern 131 formed on the upper of the base substrate 110. A first insulating layer 141 may be formed above the first circuit pattern 121 and the first dummy pattern 131. In this case, the first insulating layer 141 and the first dummy pattern 131 formed in the empty space in which the first circuit pattern 121 is not formed may be flatly formed by the slit die coating method.

In addition, the build up layer 160 may include a second circuit pattern 122 and a second dummy pattern 132 formed above the first insulating layer 141. The second insulating layer 142 may be formed above the second circuit pattern 122 and the second dummy pattern 132. In this case, the second insulating layer 142 and the second dummy pattern 132 formed in the empty space in which the second circuit pattern 122 is not formed may be flatly formed by the slit die coating method.

In addition, the build up layer 160 may include a third circuit pattern 123 and a third dummy pattern 133 formed above the second insulating layer 142. A third insulating layer 143 may be formed above the third circuit pattern 123 and the third dummy pattern 133. In this case, the third insulating layer 143 and the third dummy pattern 133 formed in the empty space in which the third circuit pattern 123 is not formed may be flatly formed by the slit die coating method.

As such, the build up layer 160 may include the uniform insulating layer regardless of the dummy pattern and the number of circuit patterns stacked by the slit die coating method.

A mounting pad 151 may be formed above the build up layer 160. The mounting pad 151 may be called a terminal for being connected with the external device such as a semiconductor chip 300 to be mounted on the upper of the printed circuit board 100.

FIG. 8 shows that the mounting pad 151 is formed above a third insulating layer 143 so as not to be connected with any of the first circuit pattern 121 to the third circuit patterns 123. However, the mounting pad 151 may be electrically connected with the first circuit pattern 121 to the third circuit pattern 123 through vias (not shown) by a design of those skilled in the art.

The bump 153 may be formed above the mounting pad 151. The bump 153 is to electrically connect the printed circuit board 100 with the semiconductor chip 300 through the mounting pad 151. The bump 153 may generally be formed of a solder.

The solder resist 152 may be formed above the build up layer 160. In addition, the solder resist 152 may be formed to surround the mounting pad 151 and the bump 153. The solder resist 152 is formed at an outermost portion of the printed circuit board 100 so as to protect the circuit pattern 120, or the like, from soldering and other external environments.

Meanwhile, the preferred embodiment of the present invention describes that the build up layer 160 is formed on only one surface of the base substrate, but is only an example and therefore, the build up layer 160 can be formed on both surface of the base substrate 110.

The printed circuit board and the method for manufacturing the same according to the preferred embodiment of the present invention simultaneously apply the dummy pattern and formed in the space in which the circuit patterns are not formed and the slit die coating method used to form the insulating layer, thereby forming the insulating layer having the uniform thickness while having the small step. In addition, the printed circuit board and the method for manufacturing the same according to the preferred embodiment of the present invention can improve the reliability of the printed circuit board by forming the insulating layer having the uniform thickness.

FIG. 9 is an exemplified diagram showing a distance between the circuit pattern and the dummy pattern of the printed circuit board according to the preferred embodiment of the present invention.

According to the preferred embodiment of the present invention, the distance between the circuit pattern 120 and the dummy pattern 130 may be represented by the following Equation 1.

$$D \leq \frac{T 2}{T 1} \times \frac{100}{1.2} \qquad 〈 Equation 1 〉$$

Here, D is the distance between the circuit pattern 120 and the dummy pattern 130. T1 is a thickness of the circuit pattern 120. In addition, T2 is a maximum thickness of the insulating layer 140 formed above the circuit pattern 120 or the dummy pattern 130.

As the distance between the circuit pattern 120 and the dummy pattern 130 is increased, the step between the thickness of the insulating layer 140 formed between the circuit pattern 120 and the dummy pattern 130 and the thickness of the insulating layer 140 formed above the circuit pattern 120 or the dummy pattern 130 may be increased. Therefore, as the distance between the circuit pattern 120 and the dummy pattern 130 is increased, it may be difficult to form the planarized insulating layer 140.

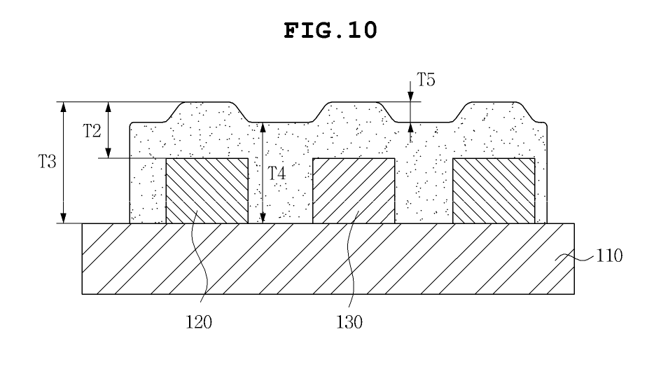

FIG. 10 is an exemplified diagram showing flatness of an insulating layer of the printed circuit board according to the preferred embodiment of the present invention.

Referring to FIG. 10, the flatness of the insulating layer 140 on the printed circuit board can be appreciated. The flatness may be excellent as the difference between the maximum thickness and the minimum thickness of the insulating layer 140 is small.

According to the preferred embodiment of the present invention, the flatness of the insulating layer 140 can be appreciated from the following Equations 2 and 3.

T3−T4≦±0.1T2 <Equation 2>

T5≦3 um <Equation 3>

Here, T2 is the maximum thickness of the insulating layer 140 formed above the circuit pattern 120 or the dummy pattern 130. T3 is the maximum thickness of the insulating layer 140. T4 is the minimum thickness of the insulating layer 140. In addition, T5 is the difference between the maximum thickness and the minimum thickness of the insulating layer 140.

According to the preferred embodiment of the present invention, the difference between the maximum thickness and the minimum thickness of the insulating layer 140 may be 10% or less of the maximum thickness of the insulating layer 140 formed above the circuit pattern 120 or the dummy pattern 130. In addition, it can be confirmed that the difference between the maximum thickness and the minimum thickness of the insulating layer 140 is 3 or less That is, the dummy pattern and the insulating layer 140 formed by the slit die coating method according to the preferred embodiment of the present invention may have excellent flatness in which the difference between the maximum thickness T3 and the minimum thickness T4 is 3 μm or less.

According to the printed circuit board and the method for manufacturing the same according to the preferred embodiment of the present invention, the dummy patterns are formed in the space in which the circuit patterns are not formed and the insulating material is applied by the slit die coating method, thereby forming the planarized insulating layer.

The printed circuit board and the method for manufacturing the same according to the preferred embodiments of the present invention can form the dummy patterns and the planarized insulating layer by using the slit die coating method.

Although the preferred embodiments of the present invention have been disclosed for illustrative purposes, they are for specifically explaining the present invention and thus a printed circuit board and a method for manufacturing the same are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate;
circuit patterns formed in a circuit region on the base substrate;
dummy patterns formed in a dummy region on the base substrate; and
an insulating layer formed above the circuit patterns and the dummy patterns by a slit die coating method.

2. The printed circuit board as set forth in claim 1, wherein a distance between the circuit pattern and the dummy pattern is changed according to a thickness of the circuit pattern or the dummy pattern.

3. The printed circuit board as set forth in claim 1, wherein the distance between the circuit pattern and the dummy pattern is changed according to a maximum thickness of the insulating layer formed above the circuit pattern or the dummy pattern.

4. The printed circuit board as set forth in claim 1, wherein a distance between the circuit pattern and the dummy pattern is
$$D \leq \frac{T 2}{T 1} \times \frac{100}{1.2} .$$
(where D represents the distance between the circuit pattern and the dummy pattern, T1 represents the thickness of the circuit pattern, and T2 represents the maximum thickness of the insulating layer formed above the circuit pattern or the dummy pattern).

5. The printed circuit board as set forth in claim 1, wherein a difference between the maximum thickness and the minimum thickness of the insulating layer is 10% or less of the maximum thickness of the insulating layer formed above the circuit pattern or the dummy pattern.

6. The printed circuit board as set forth in claim 1, wherein a difference between the maximum thickness and a minimum thickness of the insulating layer is 3 μm or less.

7. The printed circuit board as set forth in claim 1, wherein the maximum thickness of the insulating layer is 100 μm.

8. The printed circuit board as set forth in claim 1, wherein the base substrate is an organic substrate or an organic composite substrate.

9. A method for manufacturing a printed circuit board, comprising:
preparing a base substrate;
forming circuit patterns and dummy patterns on the base substrate; and
forming an insulating layer above the circuit patterns and the dummy patterns on the base substrate by a slit die coating method.

10. The method as set forth in claim 9, wherein at the forming of the circuit patterns and the dummy patterns, a distance between the circuit pattern and the dummy pattern is changed according to a thickness of the circuit pattern or the dummy pattern.

11. The method as set forth in claim 9, wherein at the forming of the circuit patterns and the dummy patterns, the distance between the circuit pattern and the dummy pattern is changed according to a maximum thickness of the insulating layer formed above the circuit pattern or the dummy pattern.

12. The method as set forth in claim 9, wherein at the forming of the circuit patterns and the dummy patterns, a distance between the circuit pattern and the dummy pattern is
$$D \leq \frac{T 2}{T 1} \times \frac{100}{1.2} .$$
(where D represents the distance between the circuit pattern and the dummy pattern, T1 represents the thickness of the circuit pattern, and T2 represents the maximum thickness of the insulating layer formed above the circuit pattern or the dummy pattern).

13. The method as set forth in claim 9, wherein at the forming of the insulating layer, a difference between the maximum thickness and the minimum thickness of the insulating layer is 10% or less of the maximum thickness of the insulating layer formed above the circuit pattern or the dummy pattern.

14. The method as set forth in claim 9, wherein at the forming of the insulating layer, a difference between the maximum thickness and a minimum thickness of the insulating layer is 3 μm or less.

15. The method as set forth in claim 9, wherein at the preparing of the base substrate, the base substrate is an organic substrate or an organic composite substrate.

16. The method as set forth in claim 9, wherein the maximum thickness of the insulating layer is 100 μm.
